(19) United States
(12) Patent Application Publication
(10) Pub. No.: US 2021/0167068 A1
(43) Pub. Date: Jun. 3, 2021

(54) MEMORY DEVICE

(71) Applicant: NANYA TECHNOLOGY CORPORATION, New Taipei city (TW)

(72) Inventors: Wei-Chih WANG, Taoyuan City (TW); Kung-Ming FAN, Taoyuan City (TW)

(21) Appl. No.: 16/702,486

(22) Filed: Dec. 3, 2019

(51) Int. Cl. H01L 27/108; H01L 23/528; H01L 23/58

(52) U.S. Cl. CPC H01L 27/10808; H01L 27/10823; H01L 23/585; H01L 23/528

(57) ABSTRACT

A memory device includes a substrate, a first digit line, a first capacitor and a metal shield. The substrate has a plurality of active areas and an isolation area. The first digit line and the first capacitor are connected to a first active area of the active areas. The second digit line is connected to a second active area of the active areas. The metal shield is located on the insolation area and between the first digit line and the second digit line. The metal shield is electrically insulated with the first digit line and the second digit line.

### BACKGROUND

### Field of Invention

The present disclosure relates to a memory device. More particularly, the present disclosure relates to a memory device having metal shields.

### Description of Related Art

In a memory device, an intrinsic parasitic capacitor within is caused by the electric field between digit line and digit line. For DRAM array device, the digit line parasitic capacitor is critical for RC delay issue.

Accordingly, how to provide an element to solve the aforementioned problems becomes an important issue to be solved by those in the industry.

### SUMMARY

To achieve the above object, one aspect of the present disclosure is relative to a memory device with metal shields between digit line and digit line.

According to one embodiment of the present disclosure, a memory device includes a substrate, a first digit line, a first capacitor and a metal shield. The substrate has a plurality of active areas and an isolation area. The first digit line and the first capacitor are connected to a first active area of the active areas. The second digit line is connected to a second active area of the active areas. The metal shield is located on the insolation area and between the first digit line and the second digit line. The metal shield is electrically insulated with the first digit line and the second digit line.

In one or more embodiments of the present disclosure, the first capacitor is connected to a source in the first active area. The first digit line is connected to a drain in the first active area. A gate in the first active area is located between the source and the drain.

In one or more embodiments of the present disclosure, the isolation area includes shallow trench isolation, oxide, nitride or oxynitride.

In one or more embodiments of the present disclosure, the first digit line is parallel with the second digit line. In some embodiments, a gap is between the first digit line and the second digit line. The metal shield has a length along a direction from the first digit line to the second digit line. The length of the metal shield is in the range of 40% to 60% of the gap.

In one or more embodiments of the present disclosure, a height of the metal shield is greater or equal to a height of any of the first digit line and the second digit line.

In one or more embodiments, a height of the first digit line is equal to a height of the second digit line. A height of the metal shield is in the range of 70% to 130% of the height of the first digit line.

In one or more embodiments of the present disclosure, the memory device further includes a second capacitor. The second capacitor is connected to the second active area. The first capacitor and the second capacitor are located between the first digit line and the second digit line. The metal shield is located between the first capacitor and the second capacitor. In some embodiments, a height of the metal shield is smaller than a height of any of the first capacitor and the second capacitor.

In one or more embodiments of the present disclosure, the memory device further includes a spacer. The spacer is configured to cover any of the first digit line, the second digit line and the first capacitor. The spacer is formed by at least one insulator.

In one or more embodiments of the present disclosure, the material of the metal shield includes Aluminum, Tungsten, Tungsten-silicide, Copper and poly-silicon.

In summary, the metal shield is configured to shield the electric field between the first digit line and the second digit line. The parasitic capacitor in the memory device is reduced by the metal shield. In some embodiments, the metal shield further shields the electric field between the first capacitor and the second capacitor. Therefore, the RC delay issue in the memory device is improved.

It is to be understood that both the foregoing general description and the following detailed description are by examples, and are intended to provide further explanation of the disclosure as claimed.

### BRIEF DESCRIPTION OF THE DRAWINGS

The advantages of the present disclosure are to be understood by the following exemplary embodiments and with reference to the attached drawings. The illustrations of the drawings are merely exemplary embodiments and are not to be considered as limiting the scope of the disclosure.

FIG. 1 is a schematic top view of a memory device according to an embodiment of the present disclosure.

FIG. 2 is a cross-section along the line A-A′ in FIG. 1.

FIG. 3 is a cross-section along the line B-B′ in FIG. 1.

FIG. 4 is a cross-section along the line C-C′ in FIG. 1

### DETAILED DESCRIPTION

Reference will now be made in detail to the embodiments of the present disclosure, examples of which are illustrated in the accompanying drawings. Wherever possible, the same reference numbers are used in the drawings and the description to refer to the same or like parts.

In addition, terms used in the specification and the claims generally have the usual meaning as each terms are used in the field, in the context of the disclosure and in the context of the particular content unless particularly specified. Some terms used to describe the disclosure are to be discussed below or elsewhere in the specification to provide additional guidance related to the description of the disclosure to specialists in the art.

Phrases “first,” “second,” etc., are solely used to separate the descriptions of elements or operations with same technical terms, not intended to be the meaning of order or to limit the disclosure.

Secondly, phrases “comprising,” “includes,” “provided,” and the like, used in the context are all open-ended terms, i.e. including but not limited to.

Further, in the context, “a” and “the” can be generally referred to one or more unless the context particularly requires. It will be further understood that phrases “comprising,” “includes,” “provided,” and the like, used in the context indicate the characterization, region, integer, step, operation, element and/or component it stated, but not exclude descriptions it stated or additional one or more other characterizations, regions, integers, steps, operations, elements, components and/or groups thereof.

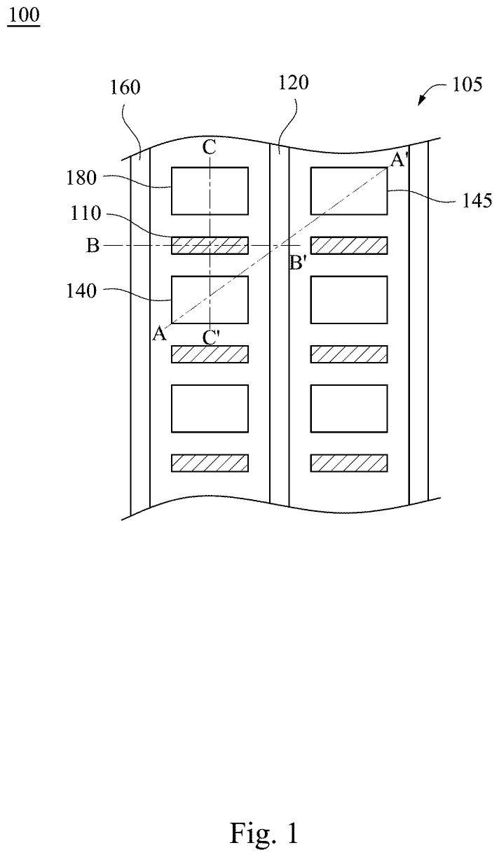

Please refer to FIG. 1. FIG. 1 is a schematic top view of a memory device 100 according to an embodiment of the present disclosure. As shown in FIG. 1, the memory device includes a substrate 105, a plurality of digit lines (e.g. first digit line 120 and second digit line 160), a plurality of capacitors (e.g. first capacitor 140, second capacitor 180 and capacitor 145) and a plurality of metal shields (e.g. metal shield 110). In this embodiment, the digit lines, the capacitors and the metal shields are located on the substrate 100. The arrangement of the digit lines, the capacitors and the metal shields on the substrate 100 is an example but not limited to the present disclosure.

The shape of the capacitors (e.g., first capacitor 140, second capacitor 180 and capacitor 145) in FIG. 1 is cuboid. The shape of the metal shield 110 is cuboid. However, the shape of the capacitors or metal shield 110 shown in FIG. 1 is an example but not limited to the present disclosure. In some embodiments, the shape of the capacitors is like a bump with a smooth top.

In this embodiment, both the first digit line 120 and the second digit line 160 are straight conductive line and parallel with each other but not limited to this present disclosure. In some embodiments, the digit lines in the memory device can be bending lines. In some embodiments, the digit lines in the memory can be not parallel with each other but not intersect.

As shown in FIG. 1, the metal shield 110 is located between the first digit line 120 and the second digit line 160. The spacing is between the metal shield 110 and first digit line 120, the second digit line 160, the first capacitor 140, and the second capacitor 180. The metal shield 110 is configured to shield the electric field between the first digit line 120 and the second digit line 160. In this embodiment, the first capacitor 140 and the second capacitor 180 are located between the first digit line 120 and the second digit line 160, and the metal shield 110 is located between the first capacitor 140 and the second capacitor 180. Therefore, the electric field between the first capacitor 140 and the second capacitor 180 can be shielded by the metal shield 110.

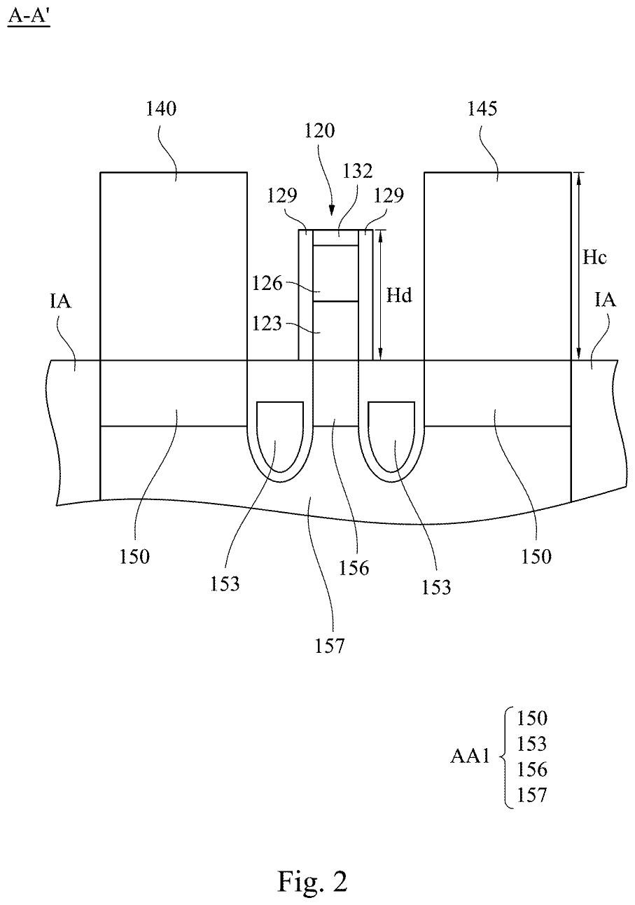

The substrate 105 includes a plurality of active areas and an isolation area. Please refer to FIG. 2. FIG. 2 is a cross-section along the line A-A′ in FIG. 1 and illustrates a first active area AA1 under the first capacitor 140, capacitor 145 and a first digit line 120. Gaps are between the first digit line 120 and the first capacitor 140 and between the first digit line 120 and the capacitor 145. The isolation regions IA are at the two side of the first active area AA1 in the substrate 105.

In some embodiments, the isolation region IA includes shallow trench isolation (STI), oxide, nitride or oxynitride.

The first capacitor 140 and the capacitor 145 are connected to the active area AA1. In this embodiment, a height Hd of the first digit line 120 is smaller than a height Hc of any of the capacitors (e.g., first capacitor 140 and capacitor 145).

Specifically, as shown in FIG. 2, the first active area AA1 includes source regions 150, gate regions 153, a drain region 156 and a channel region 157. A source region 150 is under and connected to the first capacitor 140. The drain region 156 is under and connected to the first digit line 120. A gate region 153 is located between the source region 150 under the first capacitor 140 and the drain region 156 under the first digit line 120. The channel region 157 in the first active area AA1 can be used as a channel adjacent the gate region 153 and between the source region 150 and the drain region 156.

Therefore, the first active area AA1 can be used as a transistor connected to the first digit line 120 and the first capacitor 140, and the first digit line 120, the first capacitor 140 and the first active area AA1 form a 1T1C memory cell. The 1T1C memory cell can be controlled to save information by connecting the gate regions 153 and capacitors (e.g., first capacitor 140 or capacitor 145) to a driving circuit.

Similarly, the capacitor 145, the first digit line 120 and the first active area AA form another 1T1C memory cell. Return to the FIG. 1, in this embodiment, the second capacitor 180 and the second digit line 160 can form a 1T1C memory cell in the similar way through a second active area AA2 (described below). In this embodiment, the memory device 100 is an array of 1T1C memory cell but not limited to the present disclosure.

Please return to FIG. 2. In some embodiments, the substrate 105 is a semiconductor substrate. The source regions 150 and the drain region 156 can be N+ doped regions. The gate regions 153 can be P doped regions.

As an example but not limited to the present disclosure, in this embodiment, the first digit line 120 includes two conductive regions. The first digit line 120 has a poly-silicon region 123 and a metal region 126, and the metal region 126 is form over the poly-silicon region 140. As shown in FIG. 2, in this embodiment, the first digit line 120 further includes insolation sidewalls 129 and a cap 132. The insolation sidewalls 129 and the cap 132 form a spacer coving the poly-silicon region 123 and the metal region 126. The covering spacer can electrically isolate the first digit line 120 and the metal shield 110.

In some embodiments, the material of the metal region 126 includes Tungsten (W). In some embodiments, the material of the insolation sidewalls 129 includes oxynitride. In some embodiments, the material of the cap 132 includes oxide, nitride or air.

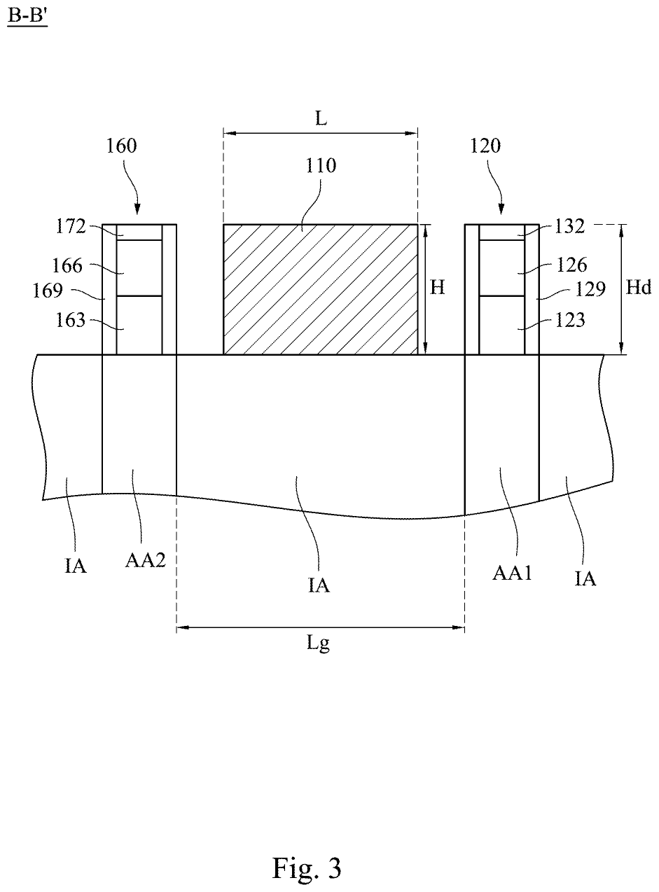

Please refer to FIG. 3. FIG. 3 is a cross-section along the line B-B′ in FIG. 1. As shown in FIG. 3, the metal shield 110 is located on the insolation region IA. The spacing is between the metal shield 110 and first digit line 120, the second digit line 160. The metal shield 110 on the insolation region IA is electrically insulated with the first digit line 120 on the first active area AA1 and the second digit line 160 on the second active area AA2.

There are some filling materials filled in the spacing of the memory device 100. For illustrative purposes, the filling materials are omitted in FIGS. In some embodiments, the filling materials include dielectric material. In some embodiments, the filling materials further include insulation materials (e.g. oxide, nitride or oxynitride).

As shown in FIG. 3, in this embodiment, the second digit line 160 located on the second active area AA2 has a poly-silicon region 163, a metal region 166 and a spacer having insolation sidewalls 169 and a cap 172.

The parasitic capacitor is caused by the electric field between the first digit line 120 and the second digit line 160. As the memory device 100 operating, the currents flow through the first digit line 120 and the second digit line 160 respectively. Therefore, an electric field is between the first digit line 120 and the second digit line 160 and an intrinsic capacitor connected to the memory device 100. The intrinsic digit line parasitic capacitor is critical for RC delay issue.

As shown in FIG. 3, the metal shield 110 has a length L along a direction from the first digit line 120 to the second digit line 160. For the purpose of the electrical isolation between the metal shield 110 and any of the first digit line 120 to the second digit line 160, the length L is smaller than a gap Lg between the first digit line 120 to the second digit line 160. In some embodiments, the length L is in the range of 40% to 60% of the gap Lg.

In this embodiment, the first digit line 120 and the second digit line 160 have the same height Hd, and the metal shield 110 has a height H similar to the height Hd such that most of the electric field can be shielded. For the purpose of shielding, in some embodiments, height H of the metal shield 110 is equal or greater than the height Hd. In some embodiments, the height H is in the range of 70% to 130% of the height Hd.

In some embodiments, the material of the metal shield includes Aluminum, Tungsten, Tungsten-silicide, Copper and poly-silicon.

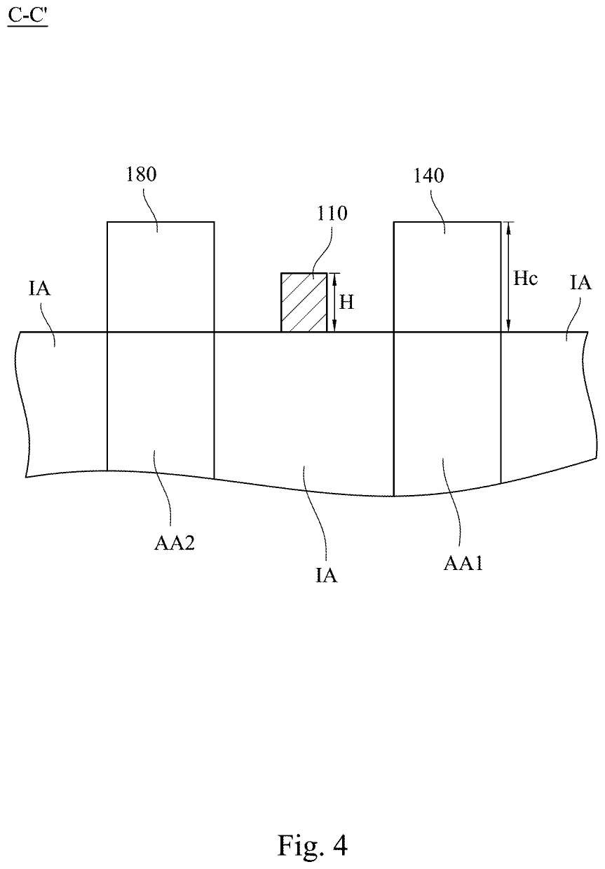

Please refer to FIG. 4. FIG. 4 is a cross-section along the line C-C′ in FIG. 1 and illustrates that the metal shield 110 is located between the first capacitor 140 and the second capacitor 180. As memory device 100 operating, the first capacitor 140 and the second capacitor 180 store some electricity, and another electric field between the first capacitor 140 and the second capacitor 180 is generated. For the similar reason, in this embodiment, the metal shield 110 is located between the first capacitor 140 and the second capacitor 180 and configured to shield the electric field. For the purpose of electrical insulating the metal shield 110 and the capacitors, in some embodiments, a spacer is configured to cover any of the first capacitor 140 and the second capacitor 180. In this embodiments, the height H of the metal shield 110 is roughly equal to the height Hd of the digit lines (e.g. first digit line 120 and second digit line 160), and the height Hc of any of the capacitors (e.g., the first capacitor 140) is greater than the height H.

As described above, the first digit line 120, the first capacitor 140 and the first active area AA1 form a 1T1C memory cell, and the capacitor 145, the first digit line 120 and the first active area AA1 form another 1T1C memory cell. The metal shield 110 is located on the isolation area IA between the first active area AA1 and the second active area AA2. Therefore, the metal shield 110 is configured between the two memory cells, and an electric field between the two memory cells can be shielded by the metal shield 110. Therefore, the parasitic capacity generated by the cell-cell electric field can be reduced. The RC delay issue caused by the intrinsic parasitic capacitors can be further improved.

In summary, the metal shield is configured to shield the electric field between digit lines or elements in the memory device. As the electric is fielded by the metal shield, the intrinsic parasitic capacitor in the memory device is partially vanished. The metal shield is located between two digit lines to shield the digit line-digit line electric field. The metal shield is located in the isolation area between the two memory cells to shield the cell-cell electric field. Therefore, the total parasitic capacity in the memory device is reduced, and the RC delay issue in the memory device is improved.

Although the embodiments of the present disclosure have been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the embodiments of the present disclosure without departing from the scope or spirit of the present disclosure. In view of the foregoing, it is intended that the present disclosure cover modifications and variations of this invention provided they fall within the scope of the following claims.

What is claimed is:

1. A memory device, comprising:
a substrate having a plurality of active areas and an isolation area;
a first digit line and a first capacitor connected to a first active area of the active areas;
a second digit line connected to a second active area of the active areas; and
a metal shield disposed on the isolation area and between the first digit line and the second digit line, wherein the metal shield is electrically insulated with the first digit line and the second digit line.

2. The memory device of claim 1, wherein the first capacitor is connected to a source in the first active area, the first digit line is connected to a drain in the first active area, and a gate in the first active area is disposed between the source and the drain.

3. The memory device of claim 1, wherein the isolation area comprises shallow trench isolation, oxide, nitride or oxynitride.

4. The memory device of claim 1, wherein the first digit line is parallel with the second digit line.

5. The memory device of claim 4, wherein a gap is between the first digit line and the second digit line, the metal shield has a length along a direction from the first digit line to the second digit line, and the length is in the range of 40% to 60% of the gap.

6. The memory device of claim 1, wherein a height of the metal shield is greater or equal to a height of any of the first digit line and the second digit line.

7. The memory device of claim 1, wherein a height of the first digit line is equal to a height of the second digit line and a height of the metal shield is in the range of 70% to 130% of the height of the first digit line.

8. The memory device of claim 1, further comprising:
a second capacitor connected to the second active area, wherein the first capacitor and the second capacitor are disposed between the first digit line and the second digit line, and the metal shield is disposed between the first capacitor and the second capacitor.

9. The memory device of claim 8, wherein a height of the metal shield is smaller than a height of any of the first capacitor and the second capacitor.

10. The memory device of claim 1, further comprising:
a spacer configured to cover any of the first digit line, the second digit line and the first capacitor, wherein the spacer is formed by at least one insulator.

11. The memory device of claim 1, wherein material of the metal shield comprises aluminum, tungsten, tungsten-silicide, copper and poly-silicon.
